(19) United States
(12) Patent Application Publication
(10) Pub. No.: US 2015/0117681 A1
(43) Pub. Date: Apr. 30, 2015

(54) Acoustic Assembly and Method of Manufacturing The Same

(71) Applicant: Knowles Electronics, LLC, Itasca, IL (US)

(72) Inventors: Joshua Watson, Aurora, IL (US); John Szczech, Schaumburg, IL (US); Greg Servis, Bloomingdale, IL (US)

(21) Appl. No.: 14/524,458

(22) Filed: Oct. 27, 2014

Related U.S. Application Data
(60) Provisional application No. 61/897,592, filed on Oct. 30, 2013.

(51) Int. Cl. H04R 23/00; B81B 7/00; H04R 31/00; B81C 1/00

(52) U.S. Cl. CPC H04R 23/00; B81C 1/00269; B81B 7/0058; H04R 31/00; B81C 2203/0154; B81B 2201/0257; H04R 2201/003
USPC 381/174; 438/51

(57) ABSTRACT

A microelectromechanical system (MEMS) microphone includes a base having a port extending there through. A MEMS die is coupled to the base, and the MEMS die includes a diaphragm and a back plate. An application specific integrated circuit (ASIC) is coupled to the base and the MEMS die. A cover is coupled to the base, and the cover includes customer pads. The customer pads on the cover are connected electrically to the ASIC, and the cover is arranged to form an air tight seal with the base and enclose the MEMS die and the ASIC. The microphone is connected to a customer board at the cover and arranged such that sound enters through the port in the base.

### CROSS REFERENCE TO RELATED APPLICATION

This patent claims benefit under 35 U.S.C. §119 (e) to U.S. Provisional Application No. 61/897,592 entitled “An acoustic assembly and method of manufacturing the same” filed Oct. 30, 2013, the content of which is incorporated herein by reference in its entirety.

### TECHNICAL FIELD

This application relates to acoustic device and, more specifically, to the configuration of assemblies or housings related to these devices.

### BACKGROUND OF THE INVENTION

Different types of acoustic devices have been used through the years. One type of device is a microphone. In a microelectromechanical system (MEMS) microphone, a MEMS die includes a diagram and a back plate. The MEMS die is supported by a substrate and enclosed by a housing (e.g., a cup or cover with walls). A port may extend through the substrate (for a bottom port device) or through the top of the housing (for a top port device). In general, the MEMS die is placed directly over the port in a bottom port configuration. In any case, sound energy traverses through the port, moves the diaphragm and creates a changing potential of the back plate, which creates an electrical signal. Microphones are deployed in various types of devices such as personal computers or cellular phones.

Top port devices typically cannot achieve the same level of electro-acoustic performance as bottom port packages. In previous top port assemblies, there has been typically insufficient back volume to achieve high sensitivity. However, top port assemblies are often desirable in certain circumstances because of their layout (port orientation in relation to the customer pads). The advantage provided in layout was accompanied with negative impacts on electro-acoustic performance in these previous devices.

The above-mentioned problems have led to some user dissatisfaction with previous approaches.

### BRIEF DESCRIPTION OF THE DRAWINGS

For a more complete understanding of the disclosure, reference should be made to the following detailed description and accompanying drawings wherein:

FIG. 1 comprises a perspective view of an acoustic assembly according to various embodiments of the present invention;

FIG. 2 comprises a view of the bottom of the acoustic assembly of FIG. 1 according to various embodiments of the present invention;

FIG. 3 comprises a cutaway view taken along line A-A of FIG. 2 according to various embodiments of the present invention;

FIG. 4 comprises a perspective cutaway view of the assembly of FIG. 1, FIG. 2, and FIG. 3 according to various embodiments of the present invention;

FIG. 5 comprises a top view of the assembly of FIG. 1, FIG. 2, FIG. 3, and FIG. 4 with the cover removed according to various embodiments of the present invention;

FIGS. 6 and 7 comprise perspective and side cutaway drawings of one of the assemblies described herein used as a top port device and disposed within another electronic device according to various embodiments of the present invention; and

FIG. 8 comprises a flowchart of a method of making the devices described herein according to various embodiments of the present invention.

Skilled artisans will appreciate that elements in the figures are illustrated for simplicity and clarity. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION

Approaches are described herein that allow a bottom port device to be inserted into another electronic device (e.g., a cellular phone or personal computer) as a top port device would be disposed. In other words, the device is seemingly configured externally as a top port device and thus is arranged and disposed in the consumer device as a top port device, thereby including all the disposition advantages associated with top port devices. On the other hand, internally, the device is configured as a bottom port device with a sufficient back volume and reduced front volume that provides an increased sensitivity and flatter frequency response over top port devices.

In one aspect, a MEMS die and/or application specific integrated circuit is attached to a substrate or base. Wire bonding or flip chip approaches may be used to make the attachment. These components are covered with a cover that includes customer pads. In one example, the cover is a molded plastic part comprised of a laser direct structuring (LDS) mold material that has been laser activated and subjected to a metallization process to add customer pads on the outside of the cover. An internal layer for EMI shielding may also be provided. The cover is attached to the base, connected electrically (to the internal components), and sealed to form an air tight seal where the base and cover connect. The seal can be made using solder, epoxy, or a combination of both of these elements. The cover could also provide pads on the inside for attachment of surface mount technology (SMT) components. The package is then flipped over and used as a top port device having back volume equal to (the same as) a bottom port device. In other words, internally the device is configured as a bottom port device, but it is disposed in or into another device as a top port device.

In many of these embodiments, a microelectromechanical system (MEMS) microphone includes a base having a port extending there through. A MEMS die is coupled to the base, and the MEMS die includes a diaphragm and a back plate. An application specific integrated circuit (ASIC) is coupled to the base and the MEMS die. A cover is coupled to the base, and the cover includes customer pads. The customer pads on the cover are connected electrically to the ASIC, and the cover is arranged to form an air tight seal with the base and enclose the MEMS die and the ASIC. The microphone is connected to a customer board at the cover and arranged such that sound enters through the port in the base.

In some examples, the seal is formed with a solder, epoxy, or a combination of solder and epoxy. In other aspects, a back volume is formed between the base and the cover, and a front volume is formed that communicates with the opening.

In other examples, the port is aligned with an external gasket, and the external gasket has a gasket opening extending there through. In other aspects, the base comprises a plurality of layers. In some examples, the plurality of layers comprises one or more of a substrate layer and a copper layer. In still other examples, the substrate layer comprises one or more PCB layers. In yet other examples, the customer board resides in a cellular phone, a personal computer, or a tablet.

In others of these embodiments, an approach of making a microelectromechanical system (MEMS) microphone includes attaching a MEMS die and application specific integrated circuit (ASIC) to a base. A cover is provided and the cover includes customer pads disposed on the cover. The customer pads communicate electrically with the ASIC and the MEMS die. The cover is attached to the base, and the attachment is effective to connect the ASIC to external components via the pads and to enclose the ASIC and MEMS die. The assembled base and cover are flipped over and the cover is attached to a customer board so that the assembled base and cover appear to be a top port device to a customer. In one aspect, the cover is formed with a laser direct structuring (LDS) material that has been laser activated.

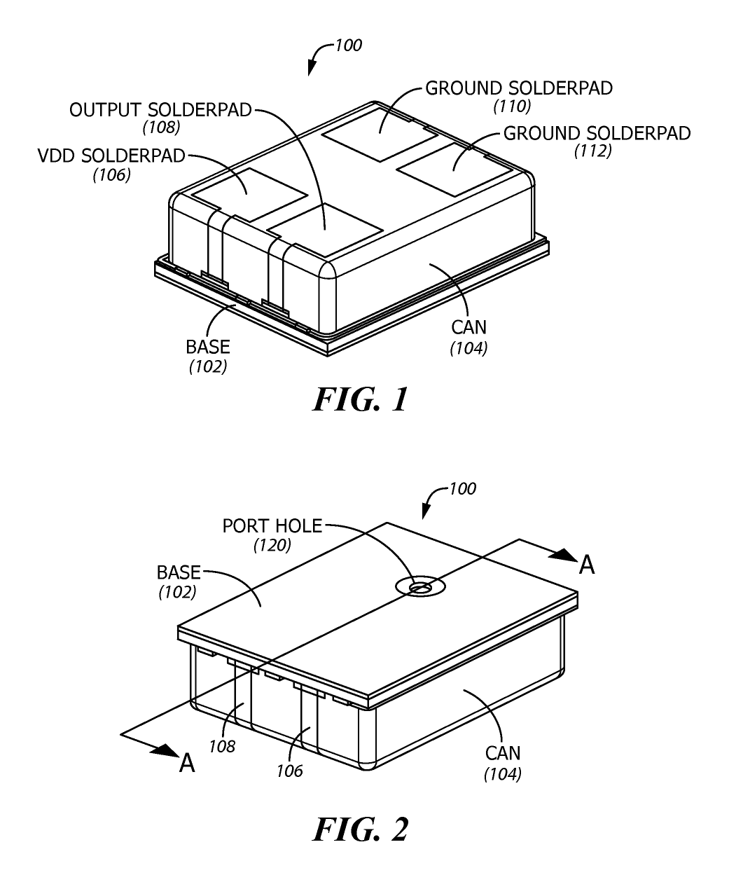

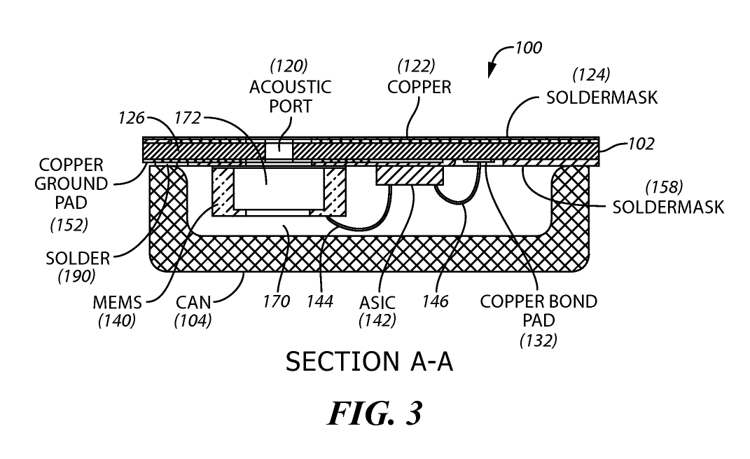

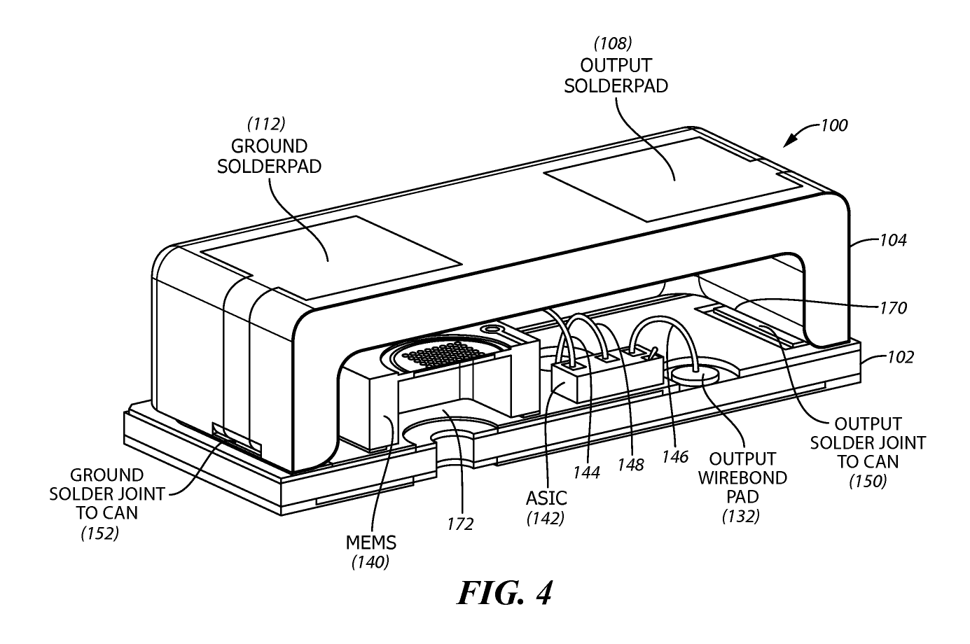

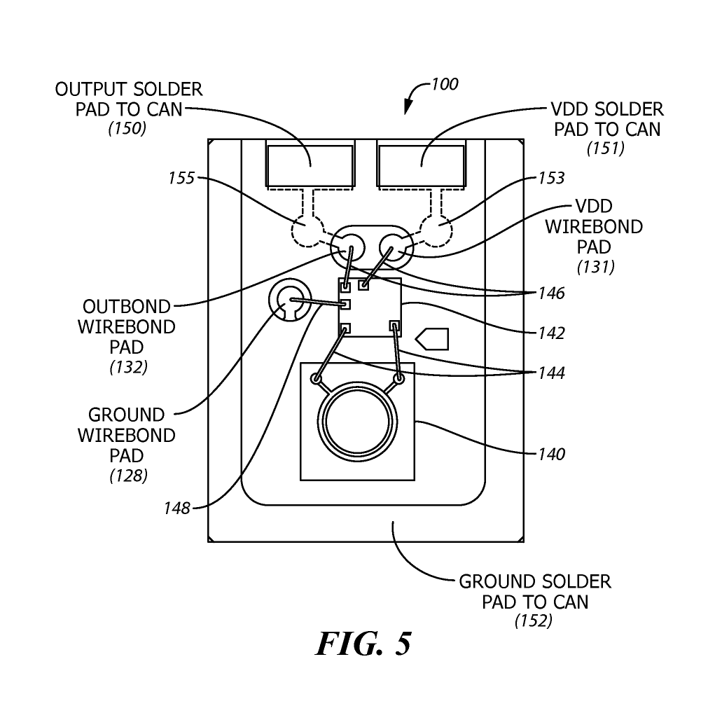

Referring now to FIG. 1, FIG. 2, FIG. 3, FIG. 4, and FIG. 5 one example of an acoustic assembly or apparatus 100 is described. The acoustic assembly 100 includes a base or substrate 102, a can or cover 104, a Vdd (supply voltage) solder pad 106, an output solder pad 108, a first ground solder pad 110, and a second ground solder pad 112. The base or substrate 102 is constructed of a number of layers that are described below. Alternatively, other layers or other arrangements of layers may be used.

In one aspect, the Vdd solder pad 106, output solder pad 108, and first ground solder pad 110 are created using a laser direct structuring (LDS) approach to mold material that can be laser activated and subjected to a metallization process to add the customer pads. The inside surfaces of the can or cover 104 can also be laser activated and subjected to a metallization process to provide a solid ground layer acting as an EMI shield. The Vdd solder pad 106, output solder pad 108, and first ground solder pad 110 extend from the top of the cover to the base and generally provide an electrical path between the base 102 (and the components secured to or through the base 102) and the device (e.g., cellular phone or personal computer) to which the assembly 100 is disposed.

The base 102 includes an acoustic port 120, a copper layer 122, a first solder mask 124, an FR4 layer 126, a copper ground pad 128, a second solder mask 130, a copper bond pad 132, and a Vdd pad 131. It will be appreciated that this is one configuration for a base and that other configurations are possible. Bismaleimide-Triazine resin (BT) layers may also be used. The base may be a printed circuit board (PCB) and utilize various PCB technologies for construction such as rigid fiber reinforced resin (e.g., FR-4, BT), flex, rigid/flex, hybrid, embedded rigid (active, passive), embedded flex (active, passive), ceramic (e.g., High Temperature Co-fired Ceramic (HTCC)/Low Temperature Co-fired Ceramic (LTCC)), and miscellaneous (including glass, silicon and even LDS). In other aspects, the PCB layers may be fiber impregnated or resin layers. Other examples are possible.

The acoustic port 120 allows sound to enter the assembly 100. The copper layer 122, copper ground pad 128, and the copper bond pad 132 provide conductive paths for electrical signals. It will be appreciated that there are conductive vias or conductors (not all are shown in the figures herein) that vertically or horizontally extend through the substrate to connect various layers. The exact path of these vias can vary and will be easily discernable to those skilled in the art.

The FR4 layer acts as an insulation layer. The function of the solder mask layers 124 and 130 are to prevent shorting between adjacent traces and to define the edges of the various solder pads. Solder 190 couples the base 102 to the cover 104. The function of a first solder joint to can 192 is to electrically connect the ground solder pad 152 to the ground solder pads 110 and 112 as well as the internal ground surface used as shielding if present on the can or cover 104. The function of a second and third solder joint to can 194 is to electrically connect the output solder pad 150 to the output solder pad 108 and connect the Vdd solder pad 151 to the Vdd solder pad 106 independently.

Disposed to the base are a MEMS die 140 and an application specific integrated circuit (ASIC) 142. Wires 144, 146, and 148 couple various ones of the MEMS die 140 or ASIC 142 to the substrate 102. A back volume 170 and a front volume 172 are created.

Sound enters the port 120. The sound moves a diaphragm (not shown) on the die 140 thereby creating a changing voltage potential with the back plate (also not shown). This creates a voltage. The voltage is transmitted over wire 144 to the ASIC 142. The output of the ASIC goes through one of the wires 146 to output wirebond pad 132. Pad 132 couples with conductor 155, to solder pad 150, and to output solder pad 108. The output solder pad 108 may be connected to a conductor within the device (e.g., a cellular phone or personal computer) in which the assembly is disposed.

Vdd is transmitted from Vdd solder pad 106 to solder pad 151, through conductor 153, to pad 131, across one of the wires 146 to the ASIC 142. Ground solder pads 110 and 112 connect to solder pad 152, through wire bond pad 128 and to ASIC 142 (over wire 148).

The cover 104 is attached to the base 102, connected electrically (to the internal components), and sealed to form an air tight seal where the base and cover connect, e.g., using solder 190. The seal can be made using solder, epoxy, or a combination of both of these elements.

The assembly 100 is then flipped over and used as a top port device having back volume equal to (the same as) a bottom port device. In other words, internally the device is a bottom port device, but it is disposed in another device as a top port device would have been.

It will be appreciated that externally the assembly 100 is configured and disposed in the consumer device as a top port device with all the disposition advantages associated with top port devices. On the other hand, internally, the assembly 100 is configured to operate as a bottom port device with a sufficient back volume that provides a sensitivity that is increased over traditional top port devices. In addition, the front volume 172 is reduced which provides a flatter frequency response over traditional top port devices.

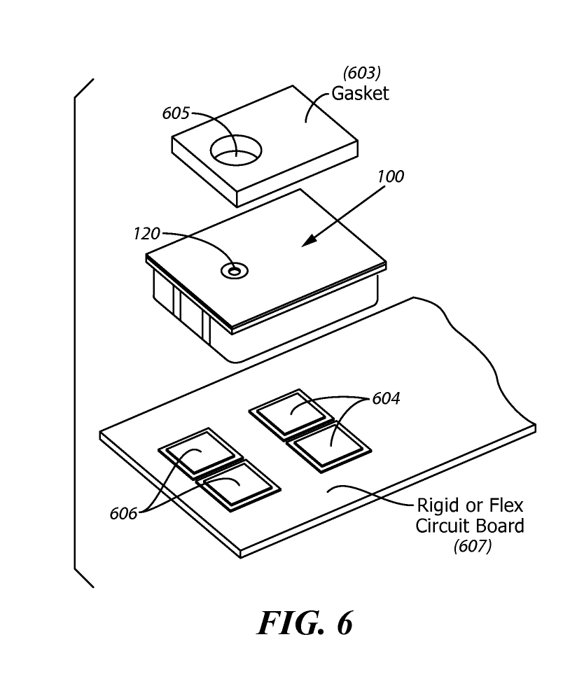

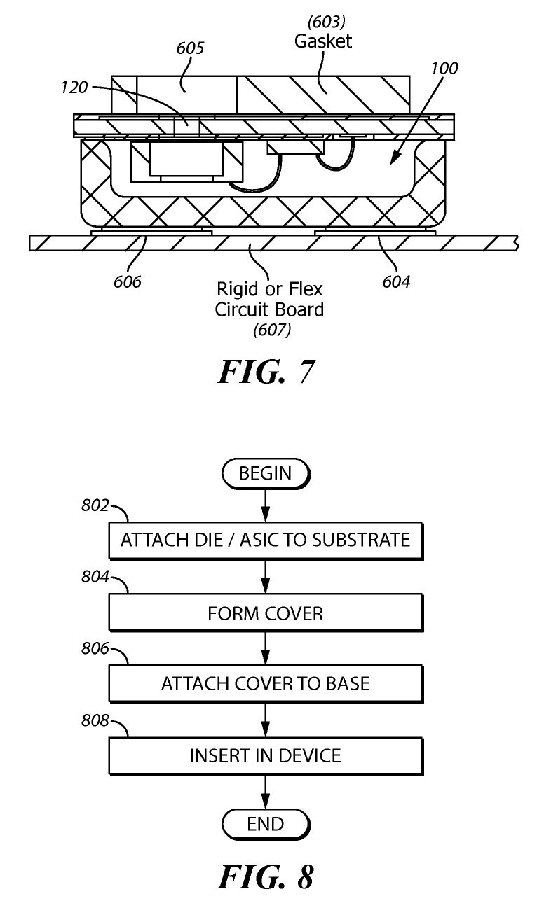

Referring now to FIG. 6 and FIG. 7, one example of having the assembly 100 of FIGS. 1-5 disposed in another electronic device is described. The other electronic device may be a cellular phone or personal computer. Other examples of devices are possible.

The assembly 100 is disposed as a top port device because the port 120 is on the top of the assembly 100, opposite the customer solder pads. A gasket 603 with opening 605 is disposed on the device 100. The assembly 100 is connected to connectors 604 and 606 disposed on a circuit board (rigid or flex) 607 of the electronic device (e.g., a cellular phone or personal computer). But, it will be appreciated that although connected as a top port device (having the port away from the side where the connection is being made), internally the assembly 100 is configured as a bottom port device. In this case, the back volume is much larger than the front volume which obtains optimal sensitivity performance. This is achieved because the cover 104 is where the pads are located that couple to connectors 604 and 606. Put another way, in contrast to typical bottom port devices, the connection is not made on the substrate, but on the cover.

The entire assembly is disposed into a housing (e.g., a plastic housing) of an electronic device. The gasket 603 is disposed on top of the assembly 100 so as to align a port (not shown) in the housing of the electronic device to the acoustic port 112 on the device 100. An air tight seal is provided between the gasket and housing of the electronic device/device 100.

Referring now to FIG. 8, one approach for making the devices described herein is described. At step 802, a MEMS die and/or application specific integrated circuit is attached to a substrate. Wire bonding or flip chip approaches may be used to make the attachment.

At step 804 a cover is formed with customer pads on the cover (e.g., a plastic part molded with a laser direct structuring (LDS) mold material that has been laser activated and subjected to a metallization process to add the customer pads on the outside of the cover and a ground plane on the inside surfaces for EMI shielding). Alternatively, a two-shot molding process may be utilized that uses the same metallization processing to add the metal traces but the conductive plastic is molded on to non-conductive plastic with two shots, instead of using a laser to activate conductive sections as with LDS.

At step 806, the cover is attached to the base, connected electrically (to the internal components), and sealed to form an air tight seal where the base and cover connect. The seal can be made using solder, epoxy, or a combination of both of these elements. The cover could also provide pads on the inside for attachment of surface mount technology (SMT) components.

At step 808, the package is then flipped over and used as a top port device having back volume equal to (the same as) a bottom port device. In other words, internally the device is a bottom port device, but it is disposed in another device as a top port device would have been.

Preferred embodiments of this invention are described herein, including the best mode known to the inventors for carrying out the invention. It should be understood that the illustrated embodiments are exemplary only, and should not be taken as limiting the scope of the invention.

What is claimed is:

1. A microelectromechanical system (MEMS) microphone, comprising:
a base having a port extending there through;
a MEMS die coupled to the base, the MEMS die including a diaphragm and a back plate;
an application specific integrated circuit (ASIC) coupled to the base and the MEMS die;
a cover coupled to the base, the cover including customer pads, the customer pads on the cover being connected electrically to the ASIC, and the cover arranged to form an air tight seal with the base and enclose the MEMS die and the ASIC;
the microphone being connected to a customer board at the cover and arranged such that sound enters through the port in the base.

2. The MEMS microphone of claim 1 wherein the seal is formed with a solder, epoxy, or a combination of solder and epoxy.

3. The MEMS microphone of claim 1, wherein a back volume is formed between the base and the cover, and a front volume is formed that communicates with the opening.

4. The MEMS microphone of claim 1, wherein the port is aligned with an external gasket, the external gasket having a gasket opening extending there through.

5. The MEMS microphone of claim 1, wherein the base comprises a plurality of layers.

6. The MEMS microphone of claim 5, wherein the plurality of layers comprises one or more of a substrate layer and a copper layer.

7. The MEMS microphone of claim 6, wherein the substrate layer comprises one or more PCB layers.

8. The MEMS microphone of claim 1, wherein the customer board resides in a cellular phone, a personal computer, or a tablet.

9. A method of making a microelectromechanical system (MEMS) microphone, comprising:
attaching a MEMS die and application specific integrated circuit (ASIC) to a base;
providing a cover, the cover with customer pads disposed on the cover, the customer pads communicating electrically with the ASIC and the MEMS die;
attaching the cover to the base, the attachment effective to connect the ASIC to external components via the pads and to enclose the ASIC and MEMS die;
flipping the assembled base and cover over and attaching the cover to a customer board so that the assembled base and cover appear to be a top port device to a customer.

10. The method of claim 9 wherein the attaching the cover forms a seal between the cover and the base, the seal being formed with a solder, epoxy, or a combination of solder and epoxy.

11. The method of claim 9, wherein a back volume is formed between the base and the cover, and a front volume is formed to communicate with the opening.

12. The method of claim 9, further comprising aligning the port with an external gasket, the external gasket having an opening extending there through.

13. The method of claim 9, wherein the base comprises a plurality of layers.

14. The method of claim 13, wherein the plurality of layers comprises one or more of a substrate layer and a copper layer.

15. The method of claim 14, wherein the substrate layer comprises one or more PCB layers.

16. The method of claim 9, wherein the customer board resides in a cellular phone, a personal computer, or a tablet.

17. The method of claim 9, wherein the cover is formed with a laser direct structuring (LDS) material that has been laser activated.
